(19) United States
(12) Patent Application Publication
(10) Pub. No.: US 2015/0311143 A1
(43) Pub. Date: Oct. 29, 2015

(54) LEAD FRAMES HAVING METAL TRACES WITH METAL STUBS

(71) Applicants: Chee Seng Foong, Sg Buloh (MY); Boon Yew Low, Petaling Jaya (MY); Zi Song Poh, Melaka (MY)

(72) Inventors: Chee Seng Foong, Sg Buloh (MY); Boon Yew Low, Petaling Jaya (MY); Zi Song Poh, Melaka (MY)

(73) Assignee: Freescale Semiconductor, Inc., Austin, TX (US)

(21) Appl. No.: 14/264,071

(22) Filed: Apr. 29, 2014

(51) Int. Cl. H01L 23/495; H01L 23/31

(52) U.S. Cl. CPC H01L 23/49503; H01L 23/3107; H01L 23/49537; H01L 23/49541

(57) ABSTRACT

A lead frame has a trace embedded in an encapsulant and a plurality of stubs (i) embedded in the encapsulant and (ii) connected to and extending from the trace at different locations along the length of the trace. The stubs inhibit the formation of cracks that may otherwise form along the trace due to thermal or mechanical bending of the lead frame, especially cracks that tend to occur along the four linear edge traces located at the periphery of some conventional embedded lead frames.

### BACKGROUND

The present invention relates generally to semiconductor packaging, and, more particularly, to lead frames used in assembling semiconductor devices.

FIG. 1A shows a top view of one implementation of a conventional embedded lead frame 102, and FIG. 1B shows a top view of a portion of one implementation of a conventional embedded lead frame array 100 having multiple instances of the embedded lead frame 102. The lead frame array 100 is fabricated using known molded interconnection system (MIS) techniques that enable the lead frame array 100 to be relatively thin (e.g., 0.112 mm) compared to embedded lead frame arrays fabricated using other techniques.

Referring to FIG. 1A, the lead frame 102 has a pattern of metal structures embedded in an encapsulant 104 (i.e., a molding compound). In general, a lead frame is a collection of metal leads and possibly other elements (e.g., die flags and power bars) that is used in semiconductor packaging for assembling a single packaged semiconductor device. Prior to assembly, a lead frame may have support structures (e.g., a rectangular metal frame) that keep the elements of the lead frame in place. During the assembly process, the support structures may be removed. As used herein, the term “lead frame” may be used to refer to the collection of elements before assembly or after assembly, regardless of the presence or absence of those support structures.

In this particular embodiment, the lead frame 102 includes (i) a die flag 106 (also known as a die pad or die paddle), (ii) a plurality of leads 112, (iii) four corner pads 108, and (iv) four linear edge traces 110. The linear edge traces 110 connect different pairs of adjacent ones of the corner pads 108.

Each lead 112 has (i) an external pad area 114 that allows the assembled device to be connected to other devices or a printed circuit board, (ii) a wire-bond pad 118 where a bond wire is attached for connecting the lead 112 to an IC die (not shown) subsequently mounted on the die flag 106, and (iii) a lead trace 116 connecting the external pad area 114 to the wire-bond pad 118.

The external pad areas 114 are exposed or formed entirely through the encapsulant 104 so that, for example, a solder ball may be disposed on the bottom of the bond area 114 exposed on the bottom surface of the lead frame 102. The wire-bond pads 118, the lead traces 116, and the linear edge traces 110 are formed part of the way through the encapsulant 104 such that the encapsulant 104 directly under the wire-bond pads 118, the lead traces 116, and the linear edge traces 110 is thinner than in areas of the lead frame 102 where no metal structures are present.

During device assembly, one or more IC dies (not shown) are adhesively mounted on the die flag 106. Wire bonding is performed, where metal bond wires (not shown) are strung between and bonded to bond pads on each IC die and corresponding wire-bond pads 118 of the lead frame 102.

Following wire bonding, the upper surface of the lead frame 102, the IC die(s), and the bond wires are encapsulated in molding compound. The molding compound is subsequently cured. After encapsulation, solder balls (not shown) may be deposited on the exposed external pad areas 114. The solder balls, together with the leads 112, provide electrical connections between electronic components internal to the IC die and electronic components external to the packaged device. External components might include power sources and input/output connections on a printed circuit board (PCB) on which the packaged semiconductor device is mounted.

Referring to FIG. 1B, multiple packaged semiconductor devices (not shown) are typically assembled concurrently on an embedded lead frame array such as the embedded lead frame array 100. The lead frame array 100 includes (i) an array of instances (e.g., 102a-d) of the embedded lead frame 102 upon which the multiple packaged semiconductor devices are assembled and (ii) a peripheral region 120 around the perimeter of the lead frame array 100.

In FIG. 1B, one complete lead frame 102a, portions of three adjacent lead frames 102b-d, and a portion of the peripheral region 120 on the top and left-hand sides of the lead frame array 100 are shown. Although not shown, the peripheral region 120 borders all four sides of the lead frame array 100, and the lead frame array 100 may comprise additional rows and columns of instances of the lead frame 102.

The peripheral region 120 includes a plurality of cylindrical metal structures 122 (a.k.a. current stealers) embedded in the encapsulant 104. The current stealers 122 help to uniformly distribute electrical current across the surface of the lead frame array 100 during electroplating.

To separate the semiconductor packaged devices assembled on the lead frames 102a-d from one another and from the peripheral region 120, singulation is performed whereby cuts are made along dashed lines 126. Note that dashed lines 126 do not represent physical markings, but are merely provided to show where the cuts are made. Cutting along the dashed lines 126 leaves a border 128 of encapsulant 104 around the perimeter of each packaged semiconductor device as shown in FIG. 1A.

The MIS substrate or lead frame 102 is susceptible to handling and thermally induced warpage cracks along the trace-to-mold interfaces. As these lead frames 102 are ultra thin (0.112 mm total) and the mold compound 104 is thin directly below the traces, there are weaknesses in the structure. This situation is compounded when the lead frames 102 do not have a solder mask coating, which may be left off due to the increased cost involved in including such a coating. Thus, it would be beneficial to have a stronger lead frame or MIS substrate such that it is less susceptible to cracking and warpage.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1A shows a top view of one implementation of a conventional embedded lead frame;

FIG. 1B shows a top view of a portion of one implementation of a conventional embedded lead frame array having multiple instances of the embedded lead frame of FIG. 1A;

FIG. 2A shows a top view of an embedded lead frame according to one embodiment of the present invention;

FIG. 2B shows a top view of a portion of an embedded lead frame array according to one embodiment of the present invention having multiple instances of the embedded lead frame of FIG. 2A;

FIG. 3 is a cross-sectional side view of a packaged semiconductor device according to one embodiment of the present invention; and

FIG. 4 is an enlarged plan view of a portion of a lead frame according to an alternative embodiment having lead traces with metal stubs.

### DETAILED DESCRIPTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the present invention.

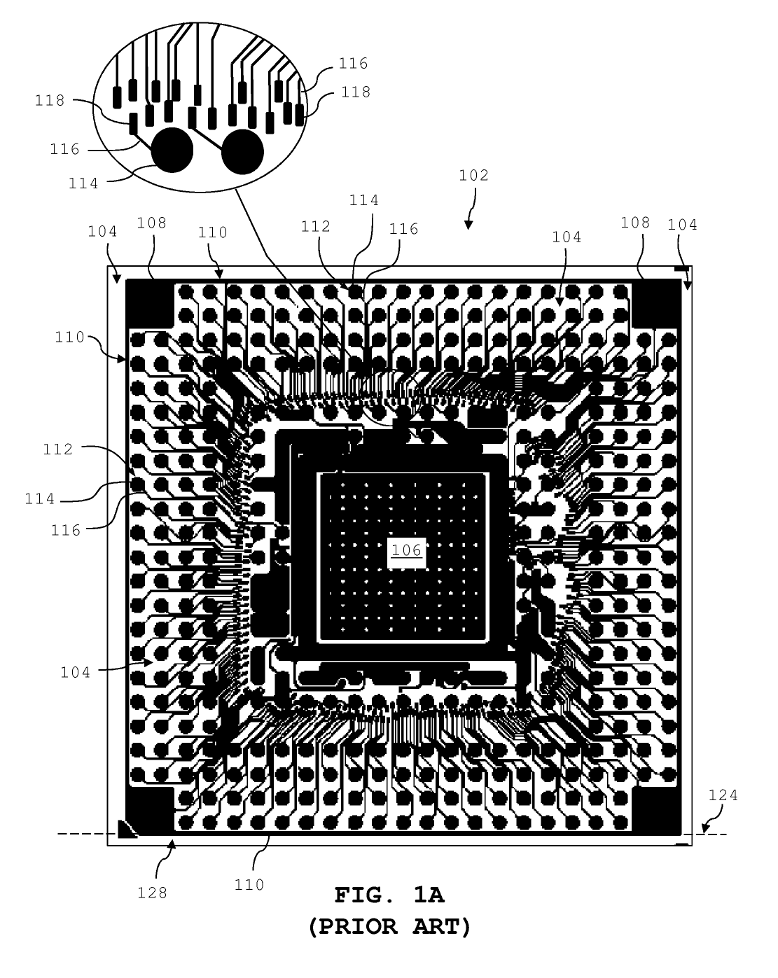

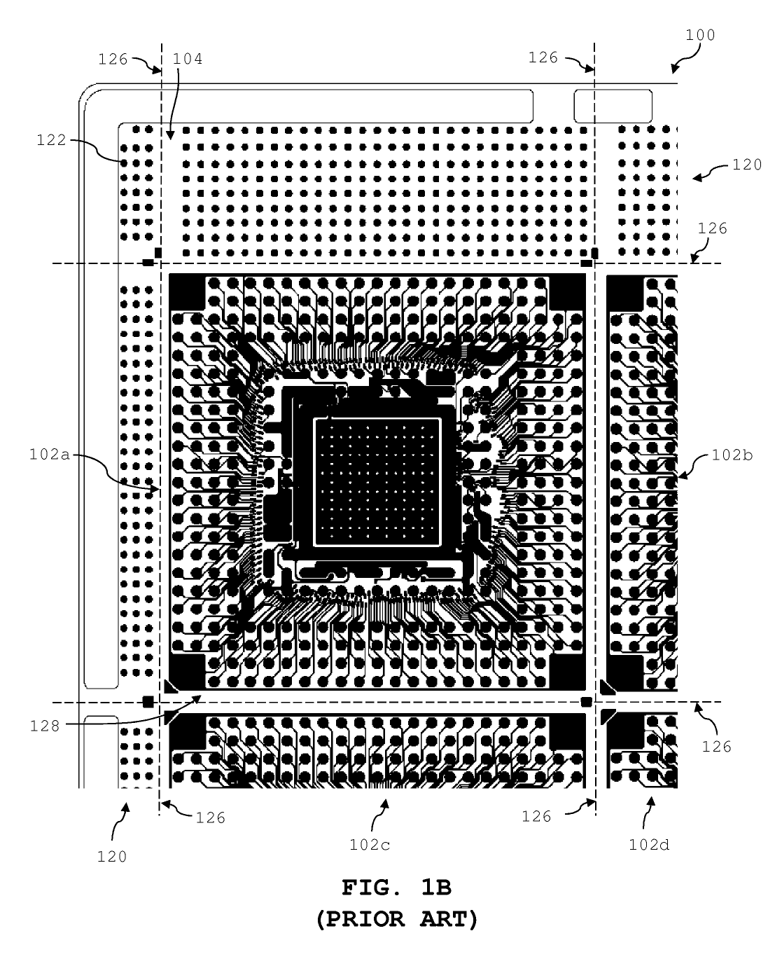

When the embedded lead frame array 100 of FIG. 1A is subjected to temperature changes, the lead frame array 100 can warp, sometimes causing the lead frame array 100 to crack. Further, the lead frame array 100 can crack during normal handling of the lead frame array 100. Typically, cracks form at the interface between (i) an elongated trace, such as one of the linear edge traces 110 of lead frame 102, and (ii) the encapsulant 104. This may be due, at least in part, to the reduced thickness of the encapsulant 104 under the elongated trace. Such cracking may be even more likely to occur when the upper surface of the lead frame array 100 is not coated with soldermask to cut costs.

When a crack forms, the crack tends to propagate entirely through the thickness of the lead frame array 100 and along the length of the elongated trace. For example, a crack could propagate through the lead frame 102 of FIG. 1A along the dashed line 124 defined by the bottom edge of the lead frame 102. In this case, the lower border 128 of the lead frame 102 (i.e., below dashed line 124 in the view shown in FIG. 1A) becomes separated from the adjacent linear edge trace 110, thereby exposing the adjacent linear edge trace 110 of the lead frame 102 to the ambient environment.

In the following description, it will be understood that certain embodiments of the present invention are directed to lead frames comprising metal features for preventing cracks such as those discussed above and articles of manufacture comprising such lead frames. Although one particular type of lead frame is described in the embodiment below, it will be understood that embodiments of the present invention are not so limited. According to alternative embodiments of the present invention, these metal features can be implemented in other suitable types of lead frames.

In one embodiment of the present invention, an article of manufacture comprises a lead frame, wherein the lead frame comprises a trace embedded in an encapsulant, and a plurality of stubs (i) embedded in the encapsulant and (ii) connected to and extending from the trace at different locations along the length of the trace.

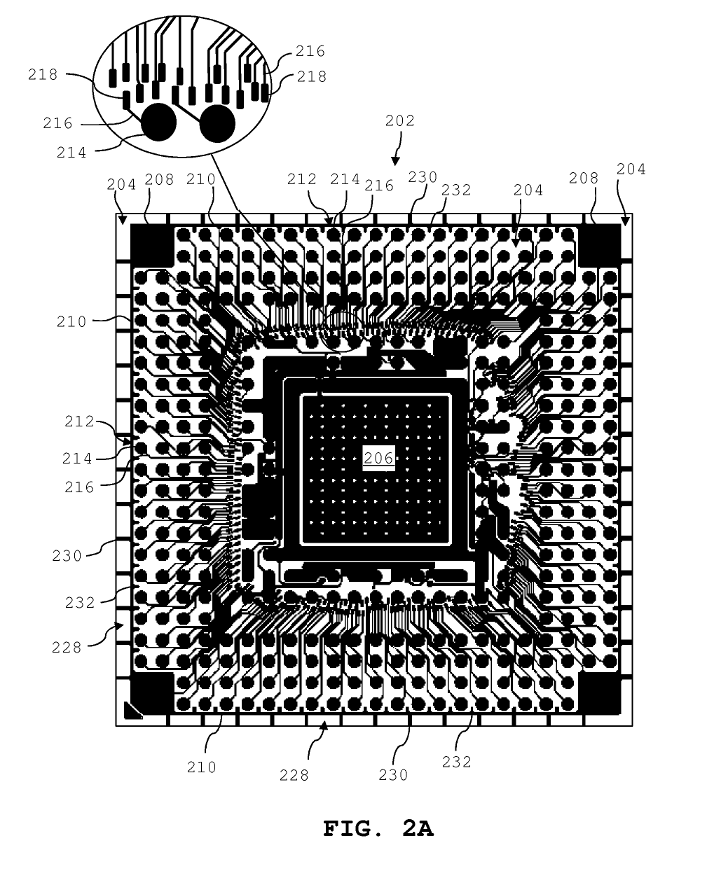

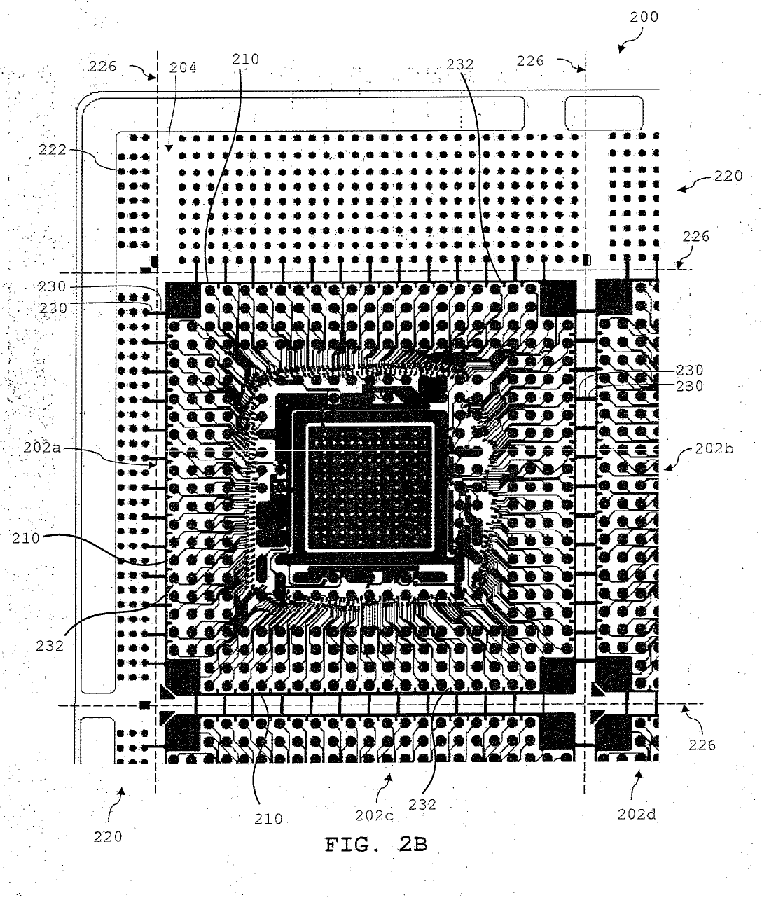

FIG. 2A shows a top view of an embedded lead frame 202 according to one embodiment of the present invention, and FIG. 2B shows a top view of an embedded lead frame array 200 according to one embodiment of the present invention that comprises multiple instances of the lead frame 202. The lead frame 202 comprises a pattern of metal structures embedded in an encapsulant 204 such as a molding compound, where the metal pattern comprises (i) a die flag 206, (ii) a plurality of leads 212, (iii) four corner pads 208, and (iv) four linear edge traces 210, which are similar to the analogous components in FIG. 1A.

In addition, the lead frame 202 comprises a plurality of outer metal stubs 230 and inner metal stubs 232. Each outer metal stub 230 extends from a linear edge trace 210 of a lead frame 202 to an edge of the encapsulant border 228 of the lead frame 202. Each inner metal stub 232 extends from a linear edge trace 210 of a lead frame 202 away from the peripheral edge of the lead frame 202 and terminates before reaching any other metal structures. In this embodiment, each inner stub 232 is positioned between a different pair of adjacent external pads 214 along the perimeter of lead frame 202; however, other spacings are possible. For example, the inner stubs 232 could be spaced between every other external pad 214.

The metal stubs 230 and 232 strengthen the lead frame 202 such that the lead frame 202 is less susceptible to cracking than the lead frame 102 of FIG. 1A. In particular, the metal stubs 230 and 232 inhibit bending along the sides of the linear edge traces 210 due to handling and/or temperature-induced warping, where such bending could ultimately lead to cracks.

Referring now to FIG. 2B, similar to the embedded lead frame array 100 of FIG. 1B, the embedded lead frame array 200 comprises an array of instances (e.g., 202a-d) of the lead frame 202 and peripheral region 220 around a perimeter of the lead frame array 200. The peripheral region 220 comprises a plurality of cylindrical metal structures 222, analogous to the cylindrical metal structures 122 in FIG. 1B, which are embedded in the encapsulant 204.

In this embodiment, each outer metal stub 230 of each lead frame 202a-d is interconnected with either (i) an outer metal stub 230 of an adjacent lead frame or (ii) a cylindrical metal structure 222 of an adjacent portion of the peripheral region 220. The outer stubs 230 are spaced by a distance that is equal to the distance between every other cylindrical metal structure 222; however, other spacings are possible.

Overall, interconnecting the lead frames 202a-d to one another and to the peripheral region 220 using the outer metal stubs 230 provides a lead frame array structure that is more resistant to bending. Further, each metal stub 230 and 232 provides a stop that may prevent a crack from propagating along the length of a linear edge trace 210. Metal stubs 230 and 232 can be incorporated into lead frame array designs with little, if any, cost, and do not require special routing of the leads 212 to avoid the stubs 230 and 232.

Packaged semiconductor devices may be assembled on the embedded lead frames 202a-d in a manner similar to that discussed above in relation to the embedded lead frame 102 of FIG. 1A. Note, however, that the cuts made along the dashed lines 226 during singulation separate each outer metal stub 230 of each lead frame 202a-d from either (i) the corresponding metal stub 230 of an adjacent lead frame or (ii) the corresponding cylindrical metal structure 222 of an adjacent peripheral region 220. As a result, the outer metal stubs 230 of each lead frame 202a-d terminate at the outer edge of the border 228 without directly connecting to any other metal structures in the lead frame.

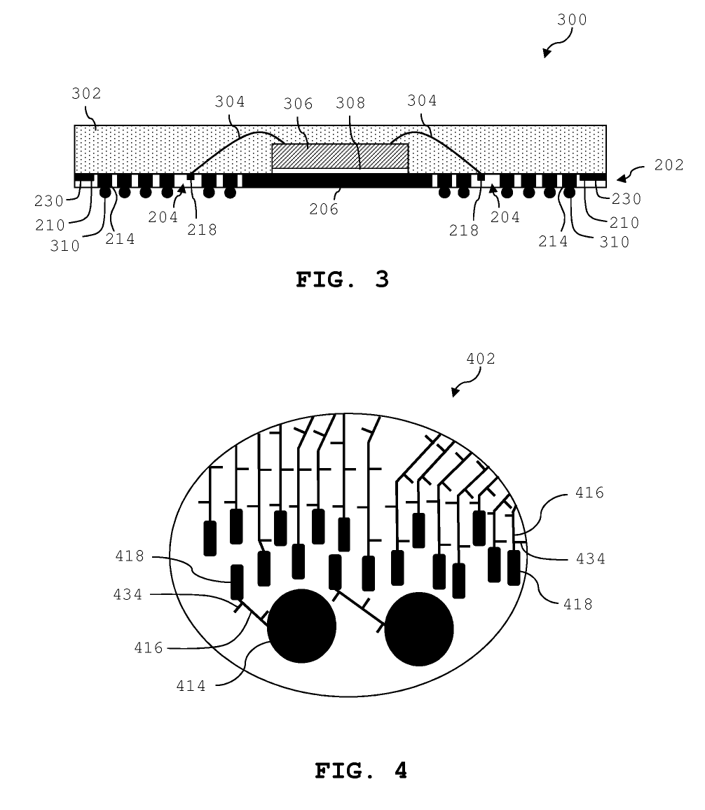

FIG. 3 shows a cross-sectional view of a packaged semiconductor device 300 assembled on the lead frame 202 of FIG. 2A according to one embodiment of the present invention. As shown, an IC die 306 is adhesively mounted on the die flag 206 using an adhesive 308 such as a die-attach tape or epoxy, and the IC die 306 is electrically connected to wire-bond pads 218 with bond wires 304. Note that the lead traces 216 shown in FIG. 2 interconnecting the wire-bond pads 218 and the external pads 214 extend into or out of the cross-sectional view of FIG. 3 and are therefore not visible in the view of FIG. 3. The upper surface of the lead frame 202, the IC die 306, and the bond wires 304 are encapsulated in a molding compound 302.

Although one embodiment of the present invention was described as implementing metal stubs 230 and 232 along linear edge traces 210 on the perimeter of lead frame 202, embodiments of the present invention are not so limited. In general, metal stubs may be implemented on any suitable trace of a lead frame.

For example, FIG. 4 shows a view analogous to the detail view of FIG. 2A of a lead frame 402 according to an alternative embodiment having lead traces 416 with metal stubs 434. As shown, the stubs 434 extend along the length of the lead traces 416 between external pads 414 and the wire-bond pads 418. The length of the stubs is limited to prevent the stubs from electrically coupling with adjacent metal structures such as adjacent lead traces 416.

Further, some embodiments of the present invention might not have linear edge traces. In such embodiments, the metal stubs may be implemented on suitable traces within the interior of a lead frame.

In general, the particular configuration of the lead frame 202 shown in FIG. 2A is merely exemplary to illustrate the use of metal stubs along a metal trace. Embodiments of the present invention are not limited to the particular lead frame configuration shown in FIG. 2A.

According to alternative embodiments of the present invention, metal stubs such as stubs 230 and 232 may be implemented on types of lead frames other than that shown in FIG. 2A, including (without limitation) pin grid array lead frames, chip-on-lead (COL) lead frames, quad-flat no-leads (QFN) lead frames, and other lead frames that manufactured in layers using additive manufacturing steps, subtractive manufacturing steps, or a combination of additive and subtractive manufacturing steps.

Further, according to alternative embodiments of the present invention, the particular features of the lead frame 202 may vary. For example, the size and shape of the lead frame 202, the number and arrangement of the leads 212, and the size and shape of the die flag 206 may vary.

Although FIG. 2A shows an embodiment in which the metal stubs 230 and 232 extend substantially perpendicularly from the linear edge traces 210, embodiments of the present invention are not so limited. According to alternative embodiments of the present invention, metal stubs may be implemented to extend from traces at angles other than 90 degrees.

Further, although FIG. 2A shows an embodiment in which metal stubs extend from both sides of a metal trace, embodiments of the present invention are not so limited. According to alternative embodiments, the metal stubs could extend from only one side of a metal trace.

Yet further, although FIG. 2B shows the outer metal stubs 230 of each lead frame 202a-d interconnecting with the outer metal stubs 230 of adjacent lead frames, embodiments of the present invention are not so limited. According to alternative embodiments of the present invention, the metal stubs of adjacent lead frames could be staggered such that they do not interconnect.

Even further, although FIG. 2B shows an embodiment of the present invention in which some of the outer metal stubs 230 extend to corresponding cylindrical metal structures 222 in the peripheral region 220, embodiments of the present invention are not so limited. According to some alternative embodiments of the present invention, the metal stubs may extend to metal structures in the peripheral region that are not cylindrical. For example, the right-most column of cylindrical metal structures could be replaced with a metal trace. According to other alternative embodiments of the present invention, the metal stubs may extend to the peripheral region without connecting to any metal structure in the peripheral region.

It will be further understood that various changes in the details, materials, and arrangements of the parts which have been described and illustrated in order to explain the nature of this invention may be made by those skilled in the art without departing from the scope of the invention as expressed in the following claims. For example, more than one IC die may be mounted onto the die flag 206. As another example, an IC die may be electrically connected to the leads of a lead frame of the present invention using electrical interconnections other than bond wires, such as flip-chip bumps. As yet another example, lead frames of the present invention may be formed using photolithography or other techniques.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Terms of orientation such as “lower,” “upper,” “horizontal,” “vertical,” “above,” “below,” “up,” “down,” “top,” “bottom,” “right,” and “left” well as derivatives thereof (e.g., “horizontally,” “vertically,” etc.) should be construed to refer to the orientation as shown in the drawing under discussion. These terms of orientation are for convenience of description and do not require that the apparatus be constructed or operated in a particular orientation.

Unless explicitly stated otherwise, each numerical value and range should be interpreted as being approximate as if the word “about” or “approximately” preceded the value of the value or range.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A lead frame, comprising:
a linear edge trace embedded in an encapsulant and extending along a perimeter of the lead frame; and
a plurality of stubs (i) embedded in the encapsulant and (ii) connected to and extending from the linear edge trace at different locations along the length of the linear edge trace, wherein the plurality of stubs includes a plurality of outer stubs extending from the linear edge trace toward the perimeter of the lead frame.

2. The lead frame of claim 1, wherein
the plurality of stubs further comprises
a plurality of inner stubs extending from the linear edge trace toward a center of the lead frame.

3. (canceled)

4. The lead frame of claim 1, wherein the plurality of stubs terminate without contacting another metal structure of the lead frame.

5. The lead frame of claim 1, wherein:
the lead frame is part of an embedded lead frame array comprising multiple instances of the lead frame;
wherein
adjacent lead frames are interconnected by the outer stubs.

6. The lead frame of claim 5, wherein:
the embedded lead frame array comprises a peripheral region on a perimeter of the embedded lead frame array; and
the lead frame adjacent to the peripheral region has two or more of the outer stubs interconnected to one or more metal structures within the peripheral region.

7. The lead frame of claim 1, wherein:
the lead frame is part of an embedded lead frame array comprising a peripheral region on a perimeter of the embedded lead frame array; and
the lead frame adjacent to the peripheral region has two or more of the outer stubs interconnected to one or more metal structures within the peripheral region.

8. The lead frame of claim 1, wherein the lead frame is used in the assembly of a packaged semiconductor device comprising:
at least one integrated circuit (IC) die mounted on and electrically coupled to the lead frame; and
a molding compound encapsulating the at least one IC die and at least a portion of the lead frame.

9. A lead frame for use in assembling a semiconductor device, the lead frame comprising:
a die flag;
a plurality of leads that surround the die flag, each lead having an external pad area, a wire-bond area, and an intermediate area that connects the external pad area with the wire-bond area;
an encapsulant that covers the die flag and the leads, wherein a surface of the external pad areas is exposed from the encapsulant;
a linear edge trace embedded in the encapsulant and extending along a perimeter of the lead frame; and
a plurality of stubs (i) embedded in the encapsulant and (ii) connected to and extending from the linear edge trace at different locations along the length of the linear edge trace, wherein the plurality of stubs comprise a plurality of outer stubs extending from the linear edge trace toward the perimeter of the lead frame, and wherein the stubs inhibit cracking of the encapsulant.

10. The lead frame of claim 9, wherein the plurality of stubs further comprises
a plurality of inner stubs extending from the linear edge traces away from the perimeter of the lead frame and towards the die flag, wherein the inner stubs are positioned between different pairs of adjacent external pad areas of adjacent leads.

11-12. (canceled)

13. The lead frame of claim 9, wherein the plurality of stubs terminate without contacting another metal structure of the lead frame.
